(19) United States
(12) Patent Application Publication
(10) Pub. No.: US 2025/0211067 A1
(43) Pub. Date: Jun. 26, 2025

(54) ENCODER

(71) Applicant: FUJI ELECTRIC CO., LTD., Kanagawa (JP)

(72) Inventors: Akira MORITA, Tokyo (JP); Takuya FURUICHI, Saitama (JP); Yasuyuki MASUNAGA, Kanagawa (JP); Kazuhiro KOIZUMI, Kanagawa (JP)

(21) Appl. No.: 18/922,981

(22) Filed: Oct. 22, 2024

(30) Foreign Application Priority Data
Dec. 26, 2023 (JP) 2023-219492

(51) Int. Cl. H02K 11/215; G01D 5/20

(52) U.S. Cl. CPC H02K 11/215; G01D 5/20; H02K 2211/03

(57) ABSTRACT

An encoder includes a power generation element including a first end portion and a second end portion spaced apart from the first end portion in a first direction, the power generation element being configured to generate power upon occurrence of a condition in which a magnetic field generated by one or more magnets fixed to a rotary shaft varies between the first end portion and the second end portion. The encoder includes a first member including a first vertical plate portion that is provided facing the first end portion and extends in a second direction intersecting the first direction, the first member being formed of a magnetic material; and a second member spaced apart from the first member, and including a second vertical plate portion that is provided facing the second end portion and extends in the second direction, and the second member being formed of the magnetic material.

### CROSS-REFERENCE TO RELATED APPLICATIONS

This application claims priority under 35 U.S.C. § 119 to Japanese Patent Application No. 2023-219492, filed Dec. 26, 2023, the contents of which are incorporated herein by reference.

### BACKGROUND

### 1. Technical Field

The present disclosure relates to an encoder.

### 2. Description of the Related Art

Patent Document 1 discloses a rotation detector for detecting a rotation amount of a rotary shaft of a motor. The rotation detector disclosed in Patent Document 1 is rotatably attached to the rotary shaft, and includes (i) a power generation magnet having four or more magnetic poles in an outer circumferential direction, (ii) at least one power generation element comprised of a magnetic sensitive portion and an induction coil, (iii) a first magnetic sensor, and (iv) a second magnetic sensor. The rotation detector disclosed in Patent Document 1 also includes a magnetic-flux controlling member whose position changes with the position of the power generation magnet due to rotation of the rotary shaft, and the magnetic-flux controlling member may generate an excitation voltage to be applied to at least one of the first magnetic sensor or the second magnetic sensor. Patent Document 1 discloses that the rotation detector drives the first magnetic sensor and the second magnetic sensor by power that is generated by the power generation element due to the rotation of the power generation magnet.

### Related-Art Document

### Patent Document

Patent Document 1: WO 2021/044758

### SUMMARY

As a battery-less encoder, the power generation element that generates the power using Barkhausen characteristics is used in some cases. At the power generation element, it is desired to efficiently generate the power via a magnetic field from the magnet.

The present disclosure provides an encoder that efficiently generates power at a power generation element.

In one aspect of the present disclosure, an encoder includes a power generation element including a first end portion and a second end portion spaced apart from the first end portion in a first direction, the power generation element being configured to generate power upon occurrence of a condition in which a magnetic field generated by one or more magnets fixed to a rotary shaft varies between the first end portion and the second end portion. The encoder includes a first member including a first vertical plate portion that is provided facing the first end portion and extends in a second direction intersecting the first direction, the first member being formed of a magnetic material. The encoder includes a second member spaced apart from the first member, and including a second vertical plate portion that is provided facing the second end portion and extends in the second direction, and the second member being formed of the magnetic material.

### BRIEF DESCRIPTION OF THE DRAWINGS

FIG. 1 is a diagram illustrating a servo motor system using an encoder according to a first embodiment.

FIG. 2 is a diagram illustrating a configuration of a servo motor using the encoder according to the first embodiment.

FIG. 3 is a diagram illustrating a circuit configuration of the encoder according to the first embodiment.

FIG. 4 is a diagram illustrating the circuit configuration of the encoder according to the first embodiment.

FIG. 5 is a diagram illustrating the circuit configuration of the encoder according to the first embodiment.

FIG. 6 is a plan view illustrating a configuration of magnets in the encoder according to the first embodiment.

FIG. 7 is a perspective view illustrating a configuration of a circuit board in the encoder according to the first embodiment.

FIG. 8 is a plan view illustrating a configuration of the circuit board in the encoder according to the first embodiment.

FIG. 9 is a cross-sectional view illustrating a configuration of the circuit board in the encoder according to the first embodiment.

FIG. 10 is a perspective view illustrating a configuration of the circuit board in the encoder according to a second embodiment.

FIG. 11 is a plan view illustrating a configuration of the circuit board in the encoder according to the second embodiment.

FIG. 12 is a bottom view illustrating a configuration of the circuit board in the encoder according to the second embodiment.

FIG. 13 is a cross-sectional view illustrating the configuration of the circuit board in the encoder according to the second embodiment.

FIG. 14 is a perspective view illustrating a configuration of the circuit board in the encoder according to a third embodiment.

FIG. 15 is a plan view illustrating a configuration of the circuit board in the encoder according to the third embodiment.

FIG. 16 is a bottom view illustrating a configuration of the circuit board in the encoder according to the third embodiment.

FIG. 17 is a diagram for describing a positional relationship between the magnets and horizontal plate portions in the encoder according to the third embodiment.

FIG. 18 is a cross-sectional view for describing the configuration of the circuit board in the encoder according to a fourth embodiment.

FIG. 19 is a diagram for describing the encoder in a first modification of the present embodiment.

FIG. 20 is a diagram for describing the encoder in a second modification of the present embodiment.

FIG. 21 is a diagram for describing the encoder in a third modification of the present embodiment.

FIG. 22 is a diagram for describing the encoder in the third modification of the present embodiment.

FIG. 23 is a diagram for describing the encoder in the third modification of the present embodiment.

### DETAILED DESCRIPTION

Hereinafter, various embodiments of the present invention will be described with reference to the drawings. In the description and drawings related with the embodiments, components having substantially the same or corresponding functional configurations may be denoted by the same numerals, and redundant description may be omitted. For ease of understanding, a scale of each part in the drawings may differ from an actual scale.

### First Embodiment

An encoder according to a first embodiment will be described as follows. The encoder according to the first embodiment includes a power generation element including a first end portion and a second end portion spaced apart from the first end portion in a first direction. The power generation element is configured to generate power upon occurrence of a condition in which a magnetic field generated by one or more magnets fixed to a rotary shaft varies between the first end portion and the second end portion. The encoder according to the first embodiment also includes a first member including a first vertical plate portion that is provided facing the first end portion and that extends in a second direction intersecting the first direction. The first member is formed of a magnetic material. In addition, the encoder according to the first embodiment includes a second member including a second vertical plate portion spaced apart from the first member. The second vertical plate portion is provided facing the second end portion, and extends in the second direction. The second member is formed of the magnetic material.

### Servo Motor System

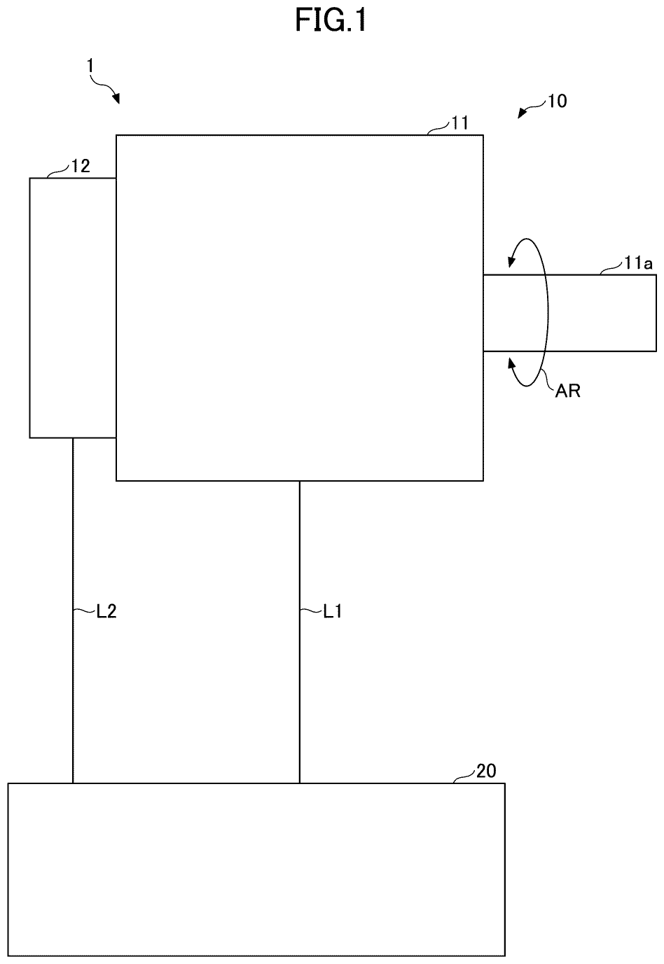

Hereinafter, a servo motor system using the encoder according to the present embodiment will be described. FIG. 1 is a diagram for describing a servo motor system 1 using an encoder 12 as an example of the encoder according to the first embodiment.

The servo motor system 1 includes a servo motor 10 and a servo controller 20. The servo controller 20 acquires, from the servo motor 10, at least one of position information or rotation information of a rotary shaft 11a. The servo controller 20 controls the servo motor 10 using the acquired at least one of the position information or the rotation information.

The servo motor 10 includes a motor 11 and an encoder 12. The motor 11 is connected to the servo controller 20 via a wire L1. The encoder 12 is connected to the servo controller 20 via a wire L2.

The motor 11 rotates a rotary shaft 11a in a direction expressed by an arrow AR, based on a command from the servo controller 20. Specifically, the rotary shaft 11a of the motor 11 rotates in the direction expressed by the arrow AR based on power that is provided by the servo controller 20. The servo controller 20 controls the motor 11 by providing controlled power to the motor 11 via the wire L1. The motor 11 includes, for example, an alternating current (AC) motor, a direct current (DC) motor, or the like.

The encoder 12 detects variations in a magnetic field, and detects at least one of the position information or the rotation information of a target, such as the rotary shaft 11a in the motor 11. The encoder 12 also outputs the detected at least one of the position information or the rotation information to the servo controller 20, via the wire L2. The position information of the rotary shaft 11a indicates, for example, an angle that is defined from the rotation direction of the rotary shaft 11a. The rotation information of the rotary shaft 11a indicates, for example, a rotation speed of the rotary shaft 11a or a number of rotations of the rotary shaft 11a that rotates after a predetermined timing.

### Servomotor 10

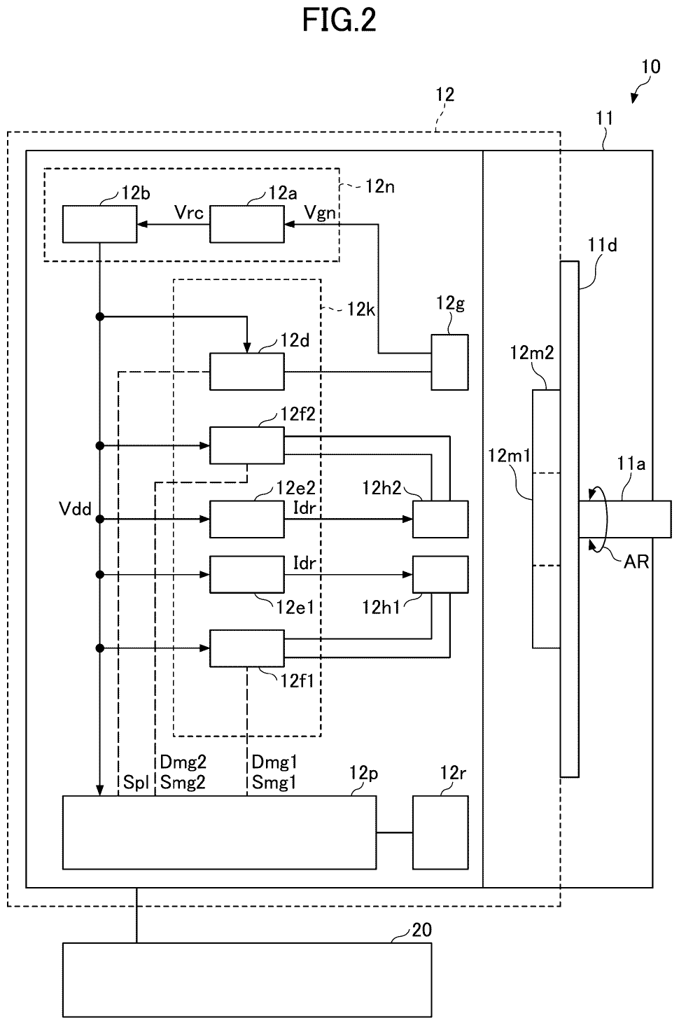

Hereinafter, the configuration of the servomotor 10 using the encoder 12 as an example of the encoder according to the first embodiment will be described. FIG. 2 is a diagram for describing the configuration of the servomotor 10 using the encoder 12 as an example of the encoder according to the first embodiment. Each line with an arrow indicates a flow of power or current delivery.

### Motor 11

In the motor 11, the rotary shaft 11a rotates. The motor 11 includes any known elements, such as a bearing for supporting the rotary shaft 11a, a winding included in a stator for rotating the rotary shaft 11a, an iron core, and a permanent magnet included in a rotor. In this description, description of the known elements is omitted. The motor 11 includes a disk 11d provided on an encoder 12-side of the rotary shaft 11a. As described below, an inner magnet 12m1 provided symmetrically with respect to the rotary shaft 11a, and an outer magnet 12m2 provided circumferentially of the rotary shaft 11a are mounted on the disk 11d.

The disk 11d is fixed to the rotary shaft 11a. The disk 11d rotates together with the rotary shaft 11a in accordance with the rotation of the rotary shaft 11a in the direction expressed by the arrow AR. The inner magnet 12m1 and the outer magnet 12m2 are fixed to the surface of the disk 11d on the encoder 12-side.

Each of the inner magnet 12m1 and the outer magnet 12m2 is a permanent magnet formed of neodymium or the like. When each of the inner magnet 12m1 and the outer magnet 12m2 rotates together with the disk 11d, the magnetic field on the encoder 12-side varies.

The inner magnet 12m1 is provided so as to have an N pole and an S pole in a direction parallel to the surface of the disk 11d. The inner magnet 12m1 generates the magnetic field to be detected by each of a first magnetic sensor 12h1 and a second magnetic sensor 12h2.

The outer magnet 12m2 generates the magnetic field that causes the power generation element 12g to generate power. The outer magnet 12m2 is arranged along the circumferential direction of the rotary shaft 11a. Details of the outer magnet 12m2 will be described below.

### Encoder 12

The encoder 12 will be described as follows. The encoder 12 detects at least one of the position information or the rotation information of the rotary shaft 11a, by using the magnetic field that changes with the rotation of the inner magnet 12m1 and the outer magnet 12m2. The encoder 12 is an absolute encoder. The encoder 12 operates as at least a multi-turn encoder. That is, the encoder 12 counts the number of rotations of the rotary shaft 11a. The encoder 12 also generates the power required to operate the encoder 12 through the magnetic field that varies with the rotation of the outer magnet 12m2.

The encoder 12 includes a power generation element 12g, a rectifier circuit 12a, a regulated power supply circuit 12b, and a polarity detection circuit 12d. The encoder 12 also includes a driver circuit 12e1, a driver circuit 12e2, a first magnetic sensor 12h1, a second magnetic sensor 12h2, a signal processing circuit 12f1, a signal processing circuit 12f2, a control circuit 12p, and a storage 12r. The encoder 12 further includes the inner magnet 12m1 and the outer magnet 12m2. The rectifier circuit 12a and the regulated power supply circuit 12b are collectively referred to as a power supply circuit 12n. The polarity detection circuit 12d, the driver circuit 12e1, the driver circuit 12e2, the signal processing circuit 12f1, and the signal processing circuit 12f2 are collectively referred to as a rotation detection circuit 12k.

The encoder 12 includes the power generation element 12g that generates the power by a change in magnetic flux due to movement, and includes a first magnetic sensor 12h1 and a second magnetic sensor 12h2 that measure the magnetic field. The power generation element 12g, the first magnetic sensor 12h1, and the second magnetic sensor 12h2 are provided on a motor 11-side of the encoder 12, so as to be easily influenced by the magnetic field generated by the inner magnet 12m1 and the outer magnet 12m2.

### Power Generation Element 12g

The power generation element 12g is an element that generates the power by converting magnetic energy into an electric pulse. The power generation element 12g is a power generation element that generates the power using Barkhausen characteristics. The power generation element 12g is, for example, a Wiegand wire that is an energy harvest generator (EHG).

The power generation element 12g includes a hard core and a soft layer wound around the hard core. The hard core is formed of a material having a greater coercive force. The soft layer is formed of a material having a smaller coercive force. The power generation element 12g generates a power generation pulse when the direction of an external magnetic field reverses.

For example, the Wiegand wire generates an electric pulse in the vicinity of a zero point where the external magnetic field reverses, without depending on a rate of change of external magnetic flux. In this arrangement, the Wiegand wire generates constant power regardless of a rotational speed of the rotary shaft 11a. The Wiegand wire generates a stable electric pulse (voltage pulse) even when the magnetic flux changes slowly due to low speed rotation (movement). The Wiegand wire generates the electric pulse at a timing at which the magnetic field reverses.

By use of an environmental generator in the power generation element 12g, the encoder 12 does not require a battery or an external power source. That is, the encoder 12 is a battery-less encoder. The Wiegand wire is suitable for use as the power generation element 12g of the encoder 12, which is a battery-less encoder, because the Wiegand wire generates the constant power regardless of the rotational speed of the rotary shaft 11a, and because a stable power generation waveform can be particularly obtained even at a low rotation speed.

The power generation element 12g is not limited to the Wiegand wire, and any power generation element that generates the power using Barkhausen characteristics may be adopted.

The power generation element 12g generates the power through the magnetic field generated by the outer magnet 12m2.

### First Magnetic Sensor 12h1 and Second Magnetic Sensor 12h2

Each of the first magnetic sensor 12h1 and the second magnetic sensor 12h2 detects the magnetic field. More specifically, each of the first magnetic sensor 12h1 and the second magnetic sensor 12h2 detects the magnetic field generated by the inner magnet 12m1 as described below.

Each of the first magnetic sensor 12h1 and the second magnetic sensor 12h2 is, for example, a Hall element. The Hall element detects a magnetic field that crosses a semiconductor element through which a drive current flows. In the encoder 12, each of the first magnetic sensor 12h1 and the second magnetic sensor 12h2 mainly detects the magnetic field generated by the inner magnet 12m1. The Hall element that constitutes each of the first magnetic sensor 12h1 and the second magnetic sensor 12h2 is, for example, a semiconductor element such as indium antimonide (InSb) or gallium arsenide (GaAs). The Hall element outputs a voltage proportional to a drive current and magnetic flux density that is across the drive current.

The first magnetic sensor 12h1 outputs a magnetic field detection signal to the signal processing circuit 12f1. A constant current Idr is delivered from the driver circuit 12e1 to the first magnetic sensor 12h1. The second magnetic sensor 12h2 outputs a magnetic field detection signal to the signal processing circuit 12f2. A constant current Idr is delivered from the driver circuit 12e2 to the second magnetic sensor 12h2.

A current (constant current Idr), which is obtained after the rectifier circuit 12a rectifies the power generated by the power generation element 12g and then the driver circuit 12e1 converts the rectified power to a constant current, is delivered to the first magnetic sensor 12h1. A current (constant current Idr), which is obtained after the rectifier circuit 12a rectifies the power generated by the power generation element 12g and then the driver circuit 12e2 converts the rectified power to a constant current, is delivered to the second magnetic sensor 12h2.

Although the encoder 12 includes two magnetic sensors, the number of magnetic sensors is not limited to two. The encoder 12 may include three or more magnetic sensors. In measuring the magnetic field, the Hall element is not limiting as long as the magnetic sensor is an element (magnetic detection element) capable of detecting magnetism. For example, a magnetoresistive element or the like may be used as the magnetic sensor.

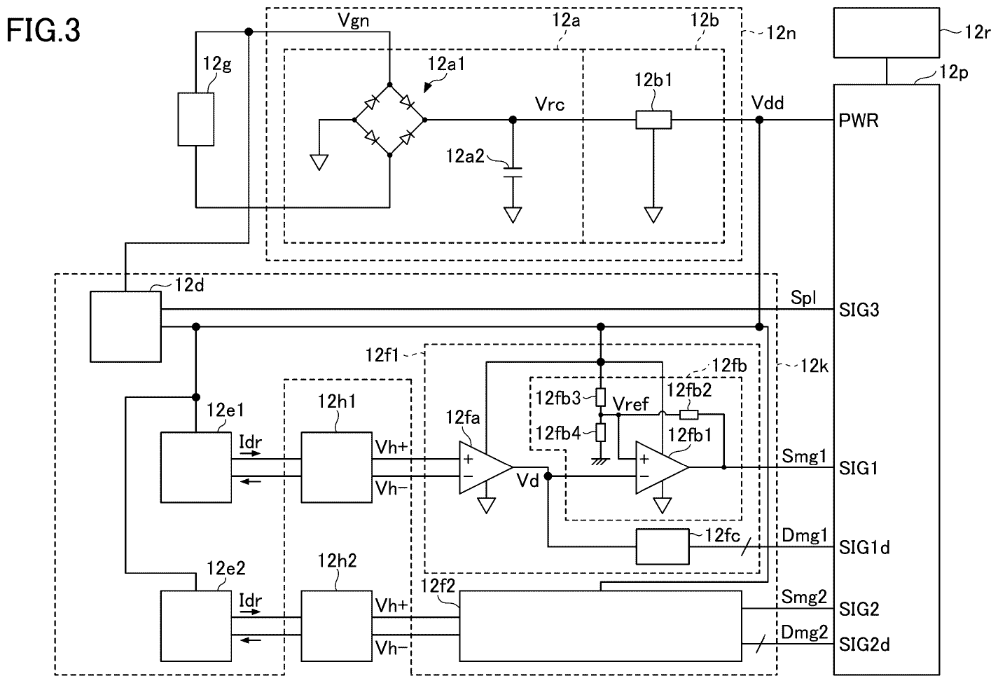

Hereinafter, a circuit configuration of the encoder 12 will be described with reference to FIG. 3. FIG. 3 is a diagram for describing the circuit configuration of the encoder 12 as an example of the encoder according to the present embodiment.

### Rectifier Circuit 12a

The rectifier circuit 12a rectifies the power generated by the power generation element 12g to generate a positive voltage. The rectifier circuit 12a includes a full-wave rectifier circuit 12a1 and a capacitor 12a2.

The full-wave rectifier circuit 12a1 rectifies a pulse having a positive level and a negative level of the voltage Vgn that is generated by the power generation element 12g, to a pulse having the positive level. The full-wave rectifier circuit 12a1 is a diode bridge circuit. For example, when the power generation element 12g is a Wiegand wire, the power generation element 12g generates the pulse having the positive level and the negative level. The full-wave rectifier circuit 12a1 converts the pulse having the positive level and the negative level, generated by the power generation element 12g, to the pulse having the positive level.

The capacitor 12a2 stores the power generated by the power generation element 12g. The capacitor 12a2 smooths the pulse having the positive level generated by the full-wave rectifier circuit 12a1. The capacitor 12a2 is provided between an output terminal of the full-wave rectifier circuit 12a1 and a common potential. When the pulse having the positive level is smoothed by the capacitor 12a2, a smoothed voltage Vrc is output from the rectifier circuit 12a.

### Regulated Power Supply Circuit 12b

The regulated power supply circuit 12b sets the voltage output from the rectifier circuit 12a to a substantially constant voltage, and outputs the substantially constant voltage. The regulated power supply circuit 12b includes a regulator 12b1. The regulator 12b1 is, for example, a low dropout (LO) regulator.

When the voltage having a predetermined magnitude is input to the regulated power supply circuit 12b, the regulated power supply circuit 12b outputs a substantially constant voltage Vdd.

### Polarity Detection Circuit 12d

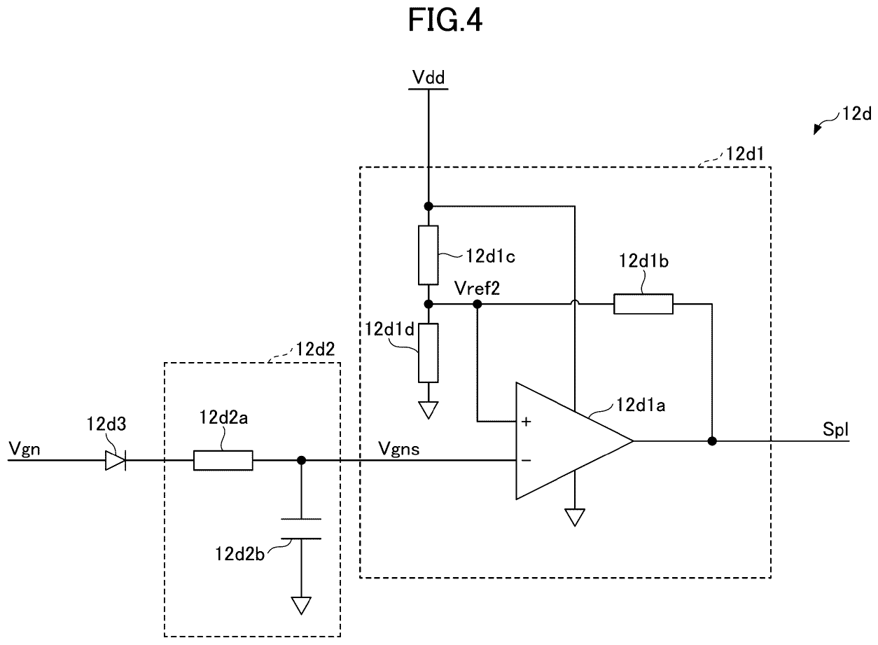

The polarity detection circuit 12d detects a polarity of the power generated by the power generation element 12g. FIG. 4 is a diagram for describing a circuit configuration of the polarity detection circuit 12d in the encoder 12. The polarity detection circuit 12d includes a comparator 12d1, a filter circuit 12d2, and a diode 12d3. The diode 12d3 prevents the current from flowing from the polarity detection circuit 12d into the power generation element 12g. The filter circuit 12d2 is a low pass filter including a resistor 12d2a and a capacitor 12d2b.

The comparator 12d1 compares a voltage Vgns with a reference potential (reference potential Vref2), and outputs a comparison result to the control circuit 12p. The comparator 12d1 is a comparator. The comparator 12d1 includes a differential amplifier 12d1a, a resistor 12d1b, a resistor 12d1c, and a resistor 12d1d. The power of the voltage Vdd is provided to the differential amplifier 12d1a from the regulated power supply circuit 12b. The differential amplifier 12d1a compares the voltage Vgns, which is obtained by smoothing the voltage Vgn output from the power generation element 12g by the filter circuit 12d2, with the reference potential Vref2, which is generated by dividing the voltage Vdd by a predetermined resistance defined by the resistor 12d1c and the resistor 12d1d. The differential amplifier 12d1a outputs the comparison result to the control circuit 12p as a polarity signal Sp1, which is a voltage signal. The resistor 12d1b is a feedback resistor.

### Driver Circuit 12e1 and Driver Circuit 12e2

The driver circuit 12e1 and the driver circuit 12e2 are constant current circuits that deliver constant currents Idr to the first magnetic sensor 12h1 and the second magnetic sensor 12h2, respectively. Each of the driver circuit 12e1 and the driver circuit 12e2 operates as a constant current source. In the encoder 12, each of the first magnetic sensor 12h1 and the second magnetic sensor 12h2, which is a Hall element, is driven by the constant current Idr.

The driver circuit 12e1 provides drive power to the first magnetic sensor 12h1 such that the constant current as a drive current flows into the first magnetic sensor 12h1 that is the Hall element. The driver circuit 12e2 provides drive power to the second magnetic sensor 12h2 such that the constant current as a drive current flows into the second magnetic sensor 12h2 that is the Hall element.

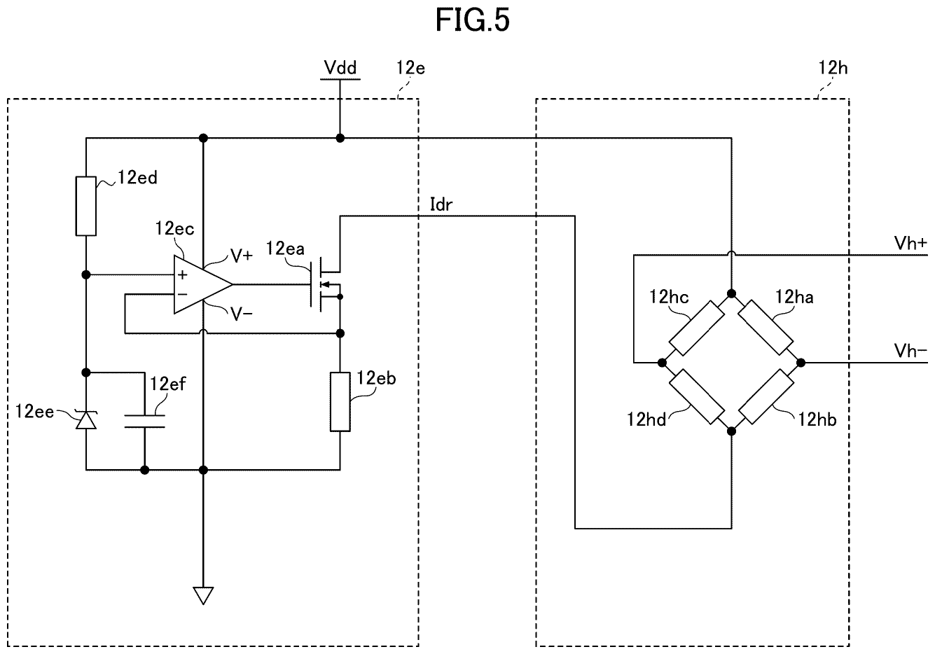

FIG. 5 is a diagram for describing a circuit configuration of the driver circuit and the magnetic sensor in the encoder 12 as an example of the encoder according to the present embodiment. The driver circuit 12e1 and the driver circuit 12e2 have the same circuit configuration, and each of the driver circuit 12e1 and the driver circuit 12e2 will be described below as a driver circuit 12e in FIG. 5. In FIG. 5, each of the first magnetic sensor 12h1 and the second magnetic sensor 12h2 as the Hall element is equivalently shown as a magnetic sensor 12h that uses a bridge circuit having a resistor 12ha, a resistor 12hb, a resistor 12hc, and a resistor 12hd.

The driver circuit 12e includes a transistor 12ea, a current detection resistor 12eb, and a differential amplifier 12ec. The driver circuit 12e also includes a resistor 12ed, a Zener diode 12ee, and a capacitor 12ef.

The transistor 12ea is controlled such that the constant current flows through the magnetic sensor 12h. An output terminal of the differential amplifier 12ec is connected to a gate of the transistor 12ea. The differential amplifier 12ec outputs a voltage obtained based on a potential difference between a + terminal and a − terminal, via the output terminal. The driver circuit 12e is controlled such that the constant current (constant current Idr), defined based on a voltage applied to the + terminal and a resistance value of the current detection resistor 12eb, flows between a drain and a source of the transistor 12ea.

The magnetic sensor 12h is driven by the constant current Idr, and outputs a voltage Vh+ and a voltage Vh−, and the voltage Vh+ is proportional to the constant current Idr and the magnetic flux density across the magnetic sensor 12h.

The driver circuit 12e is driven by the voltage Vdd supplied from the regulated power supply circuit 12b.

### Signal Processing Circuit 12f1 and Signal Processing Circuit 12f2

The signal processing circuit 12f1 and the signal processing circuit 12f2 process detection signals from the first magnetic sensor 12h1 and the second magnetic sensor 12h2, respectively, to thereby detect the direction of the magnetic field from the inner magnet 12m1. Also, each of the signal processing circuit 12f1 and the signal processing circuit 12f2 outputs the intensity of the magnetic field from the inner magnet 12m1, to the control circuit 12p, based on the detection signal from a corresponding magnetic sensor among the first magnetic sensor 12h1 and the second magnetic sensor 12h2. The signal processing circuit 12f1 and the signal processing circuit 12f2 will be described below with reference to FIG. 3. The signal processing circuit 12f1 and the signal processing circuit 12f2 have the same circuit configuration, and description of the signal processing circuit 12f1 and the signal processing circuit 12f2 will be provided below as a signal processing circuit 12f1 in FIG. 3.

The signal processing circuit 12f1 includes a differential amplifier 12fa, a comparator 12fb, and a quantizer 12fc.

### Differential Amplifier 12fa

The differential amplifier 12fa outputs, to the comparator 12fb, a voltage Vd obtained by amplifying a potential difference between the voltage Vh+ and the voltage Vh− that are output from the magnetic sensor 12h. The power of the voltage Vdd is provided to the differential amplifier 12fa from the regulated power supply circuit 12b.

### Comparator 12fb

The comparator 12fb compares the voltage Vd output from the differential amplifier 12fa with the reference potential (reference potential Vref), and outputs a comparison result to the control circuit 12p. The comparator 12fb is a comparator. The comparator 12fb includes a differential amplifier 12fb1, a resistor 12fb2, a resistor 12fb3, and a resistor 12fb4. The power of the voltage Vdd is provided to the differential amplifier 12fb1 from the regulated power supply circuit 12b. The differential amplifier 12fb1 compares the voltage Vd output from the differential amplifier 12fa with the reference potential Vref generated by dividing the voltage Vdd by a predetermined resistance define by the resistor 12fb3 and the resistor 12fb4, and outputs the comparison result to the control circuit 12p as a magnetic pole signal Smg1, which is a voltage signal. The resistor 12fb2 is a feedback resistance.

### Quantizer 12fc

The quantizer 12fc quantizes the voltage Vd output from the differential amplifier 12fa, and outputs a quantized result to the control circuit 12p. The quantizer 12fc is an analog-to-digital converter (AD converter). The quantizer 12fc quantizes the voltage Vd output from the differential amplifier 12fa, and outputs, for example, an 8-bit digital value as a magnetic field strength signal Dmg1 to the control circuit 12p.

### Control Circuit 12p

The control circuit 12p calculates at least one of position information or rotation information, based on inputs from the polarity detection circuit 12d, the signal processing circuit 12f1, and the signal processing circuit 12f2. Here, the position information includes a rotational position of the rotary shaft 11a, the number of revolutions of the rotary shaft 11a of the motor 11, and/or the like. The control circuit 12p records the detected at least one of the position information or the rotation information of the rotary shaft 11a of the motor 11, and transmits the detected at least one information to an external control system, for example, the servo controller 20.

The control circuit 12p may be, for example, implemented by a microcomputer, an application specific integrated circuit (ASIC), or the like. The control circuit 12p may be, for example, implemented by a field-programmable gate array (FPGA), a programmable logic device (PLD), or the like.

The control circuit 12p is connected to an external storage 12r. The control circuit 12p may include a nonvolatile memory such as a ferroelectric memory, instead of the external storage 12r.

The control circuit 12p includes at least teaminals that include a terminal PWR, a terminal SIG1, a terminal array SIG1d, a terminal SIG2, a terminal array SIG2d, and a terminal SIG3.

The terminal PWR in the control circuit 12p is a terminal to which positive power is provided. The power of the voltage Vdd delivered from the regulated power supply circuit 12b is provided to the terminal PWR. The control circuit 12p operates when the power is provided to the terminal PWR.

Each of the terminal SIG1, the terminal SIG2, and the terminal SIG3 of the control circuit 12p is a terminal to which a signal is externally applied. Each of the terminal array SIG1d and the terminal array SIG2d of the control circuit 12p is a terminal array to which a signal having a plurality of bits is externally applied.

The terminal SIG1 is connected to the signal processing circuit 12f1. The magnetic pole signal Smg1, which is a detection result obtained by performing detection at the signal processing circuit 12f1, is applied via the terminal SIG1. The magnetic pole signal Smg1 is a signal indicating a direction of the magnetic field detected by the first magnetic sensor 12h1. The terminal SIG2 is connected to the signal processing circuit 12f2. The magnetic pole signal Smg2, which is a detection result obtained by performing detection at the signal processing circuit 12f2, is applied via the terminal SIG2. The magnetic pole signal Smg2 is a signal indicating a direction of the magnetic field detected by the second magnetic sensor 12h2.

The terminal array SIG1d is connected to the signal processing circuit 12f1. A magnetic field intensity signal Dmg1, which is a detection result obtained by perfroming detection at the signal processing circuit 12f1, is applied via the terminal array SIG1d. The magnetic field intensity signal Dmg1 is a signal indicating the intensity of the magnetic field detected by the first magnetic sensor 12h1. The terminal array SIG2d is connected to the signal processing circuit 12f2. A magnetic field intensity signal Dmg2, which is a detection result obtained by performing detection at the signal processing circuit 12f2, is applied via the terminal array SIG2d. The magnetic field intensity signal Dmg2 is a signal indicating the intensity of the magnetic field detected by the second magnetic sensor 12h2.

The terminal SIG3 is connected to the polarity detection circuit 12d. A polarity signal Sp1, which is a detection result obtained by performing detection at the polarity detection circuit 12d, is applied via the terminal SIG3. The polarity signal Sp1 is a signal indicating a polarity of the power generated by the power generation element 12g.

The encoder 12 counts the number of rotations of the rotary shaft 11a. The control circuit 12p counts the number of rotations of the rotary shaft 11a, by using the magnetic pole signal Smg1 and the polarity signal Sp1. The control circuit 12p uses the magnetic pole signal Smg1 and the polarity signal Sp1 to determine which of the regions the rotary shaft 11a is in. Here, each the region is obtained by separating a circle defined by rotating the rotary shaft 11a once by angles of 90 degrees. The control circuit 12p stores, in the storage 12r, both a result obtained by counting the number of rotations of the rotary shaft 11a and a result obtained by determining which region the rotary shaft is in. The control circuit 12p stores, in the storage 12r, the magnetic pole signal Smg1, the magnetic pole signal Smg2, and the polarity signal Sp1, each of which is detected last.

The control circuit 12p determines a rotation angle of the rotary shaft 11a based on the magnetic field strength signal Dmg1 and the magnetic field strength signal Dmg2. For example, by use of an arctangent function, the control circuit 12p calculates the rotation angle of the rotary shaft 11a, based on a ratio of the magnetic field strength signal Dmg1 to the magnetic field strength signal Dmg2.

### Storage 12r

The storage 12r stores, for example, a rotation count value and the like. The storage 12r is, for example, a ferroelectric memory. The control circuit 12p stores, in the storage 12r, at least (i) a count value indicating the number of rotations of the rotary shaft 11a, (ii) a position of the rotary shaft, (iii) the magnetic pole signal Smg1, (iv) the magnetic pole signal Smg2, and (v) the polarity signal Sp1. Each of the magnetic pole signal Smg1, the magnetic pole signal Smg2, and the polarity signal Sp1 is detected last.

### Configuration of Encoder

Hereinafter, the configuration of the encoder 12 will be described in detail. The magnets in the encoder 12 and the circuit board will be described.

### Magnets

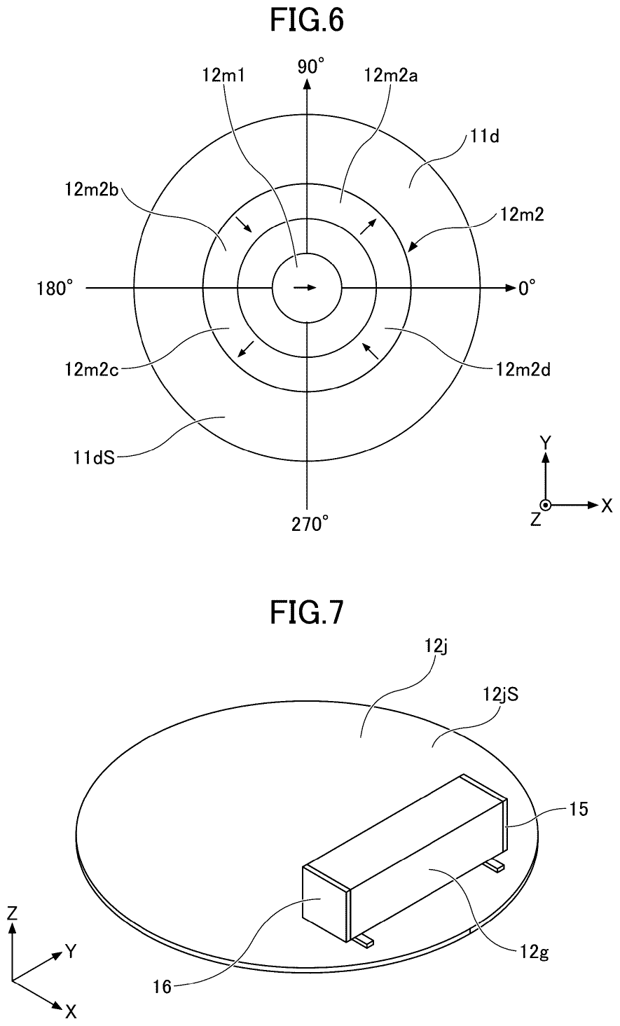

The magnets provided in the encoder 12 will be described as follows. FIG. 6 is a plan view for describing the configuration of the magnets in the encoder 12, which is an example of the encoder according to the first embodiment. In FIG. 6, each direction of magnetic flux is expressed by an arrow for the purpose of indicating the polarity of the magnet. The disk 11d rotates in synchronization with rotation of a rotation axis, and FIG. 6 is a diagram showing the arrangement of the magnets at a certain timing. In FIG. 6, zero degrees are expressed on the right side, and increased angles are expressed in a counterclockwise direction.

The encoder 12 includes the inner magnet 12m1 provided on the disk 11d, and includes the outer magnet 12m2 provided outside with respect to a rotation axis of the inner magnet 12m1. In an example, the encoder 12 includes the outer magnet 12m2 that has four poles. In the encoder according to the first embodiment, the number of poles of the outer magnet is not limited to four. For example, six poles may be adopted, or alternatively eight or more poles may be adopted.

The outer magnet 12m2 includes a magnet 12m2a in which the magnetic flux is directed outward, a magnet 12m2b in which the magnetic flux is directed inward, a magnet 12m2c in which the magnetic flux is directed outward, and a magnet 12m2d in which the magnetic flux is directed inward. The magnet 12m2a, the magnet 12m2b, the magnet 12m2c, and the magnet 12m2d are arranged circumferentially.

In the example shown in FIG. 6, in the inner magnet 12m1, the magnetic flux is oriented at 0 degrees. In the magnet 12m2a, the magnet 12m2b, the magnet 12m2c, and the magnet 12m2d of the outer magnet 12m2, the magnetic flux is oriented at 45 degrees, 315 degrees, 225 degrees, and 135 degrees, respectively.

### Circuit Board

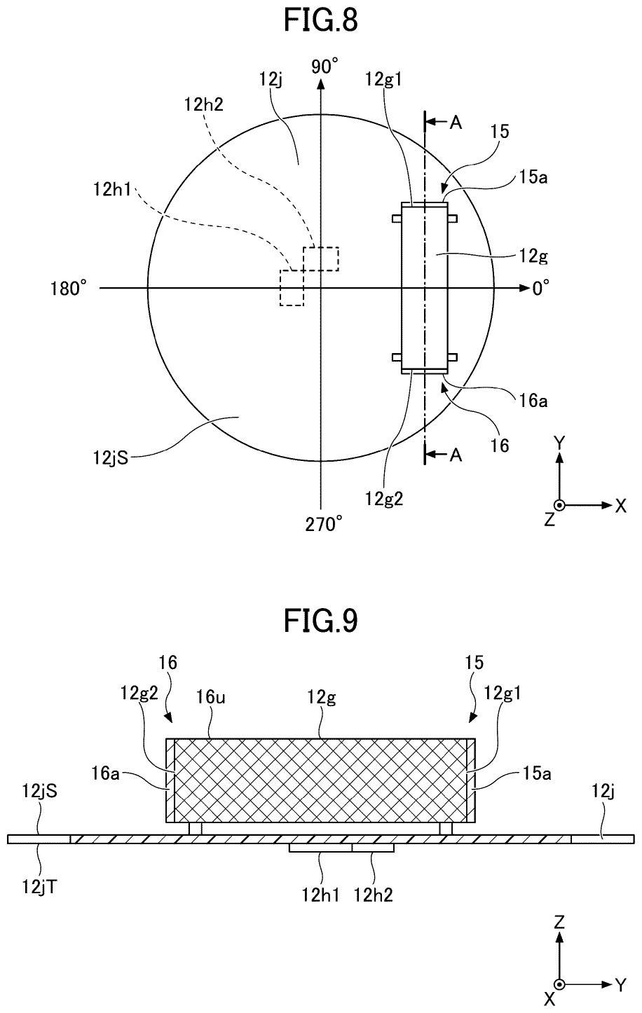

Hereinafter, a circuit board provided in the encoder 12 will be described. FIG. 7 is a perspective view for describing a configuration of the circuit board 12j in the encoder 12 as an example of the encoder according to the first embodiment. FIG. 8 is a plan view for describing the configuration of the circuit board 12j in the encoder 12 as an example of the encoder according to the first embodiment. FIG. 9 is a sectional view for describing the configuration of the circuit board 12j in the encoder 12 as an example of the encoder according to the first embodiment. FIG. 9 is a sectional view taken along the line A-A in FIG. 8. In FIG. 9, details of an internal structure of the power generation element 12g are omitted.

The circuit board 12j has a first surface 12jS and a second surface 12jT. The circuit board 12j includes a power generation element 12g on the first surface 12jS. The power generation element 12g is mounted on the first surface 12jS of the circuit board 12j. The second surface 12jT is a surface opposite the first surface 12jS on which the power generation element 12g is mounted. The second surface 12jT is a surface on a magnet side, that is, on a side where the inner magnet 12m1 and the outer magnet 12m2 are situated. The circuit board 12j includes the first magnetic sensor 12h1 and the second magnetic sensor 12h2 on the second surface 12jT.

The power generation element 12g is mounted in the circuit board 12j along a Y-axis direction. The power generation element 12g has a first end 12g1 on the +Y side, and has a second end 12g2 on the −Y side. The second end 12g2 is located apart from the first end 12g1 in the Y-axis direction. A Wiegand wire is provided inside the power generation element 12g along the Y-axis direction. The power generation element 12g generates power when the magnetic field generated by the outer magnet 12m2 fluctuates between the first end 12g1 and the second end 12g2. That is, the magnetic field via the power is generated passes through the first end 12g1 and the second end 12g2.

The encoder 12 includes a first member 15 on the +Y side of the power generation element 12g, and includes a second member 16 on the −Y side of the power generation element 12g. Each of the first member 15 and the second member 16 is made of a magnetic material.

The first member 15 includes a first vertical plate portion 15a provided facing the first end portion 12g1 of the power generation element 12g. The first vertical plate portion 15a extends along the X-axis direction and the Z-axis direction.

The second member 16 includes a second vertical plate portion 16a provided facing the second end portion 12g2 of the power generation element 12g. The second vertical plate portion 16a extends along the X-axis direction and the Z-axis direction.

In the encoder according to the first embodiment, the magnetic field generated by the outer magnet 12m2 is led to the power generation element 12g through the first member 15 and the second member 16. In this arrangement, the magnetic field can be efficiently transmitted from the outer magnet 12m2 to the power generation element 12g. In the encoder according to the first embodiment, the power generation element 12g can efficiently generate the power by efficiently transmitting the magnetic field from the outer magnet 12m2 to the power generation element 12g.

Although the widths of the first vertical plate portion 15a and the second vertical plate portion 16a along the X-axis direction are each equal to the width of the power generation element 12g along the Z-axis direction, a smaller width of at least a portion of a given vertical plate portion may be adopted as described in the modification below. Similarly, although the widths of the first vertical plate portion 15a and the second vertical plate portion 16a along the Z-axis direction are each equal to the width of the power generation element 12g along the Z-axis direction, a smaller width of at least a portion of a given vertical plate portion may be adopted.

When the width of each of the first vertical plate portion 15a and the second vertical plate portion 16a is partially decreased, at least two vertical plate portions, namely, the first vertical plate portion 15a and the second vertical plate portion 16a are arranged near respective ends of the Wiegand wire. By decreasing the widths of the first vertical plate portion 15a and the second vertical plate portion 16a, the magnetic field from the outer magnet 12m2 can be concentrated on the Wiegand wire.

Here, the Y-axis direction is used as an example of a first direction, the X-axis direction is used as an example of a second direction intersecting a first direction, and the Z-axis direction is one example of a third direction intersecting the first direction and the second direction. In the above example, the X-axis direction, the Y-axis direction, and the Z-axis direction are orthogonal to one another. However, the first direction, the second direction, and the third direction are not limited to a case where these directions are orthogonal to one another, and the above directions may intersect one another.

### Second Embodiment

Hereinafter, the encoder according to a second embodiment will be described. In the encoder according to the second embodiment, the first member in the encoder according to the first embodiment further includes a first horizontal plate portion extending in the first direction and the second direction, and the second member in the encoder according to the first embodiment further includes a second horizontal plate portion extending in the first direction and the second direction. The encoder according to the second embodiment further includes a substrate on which a power generation element is mounted. In the encoder according to the second embodiment, the first member may include a first horizontal plate portion provided on a second surface opposite a first surface of the substrate on which the power generation element is mounted, and the second member may include a second horizontal plate portion provided on the second surface.

### Circuit Board

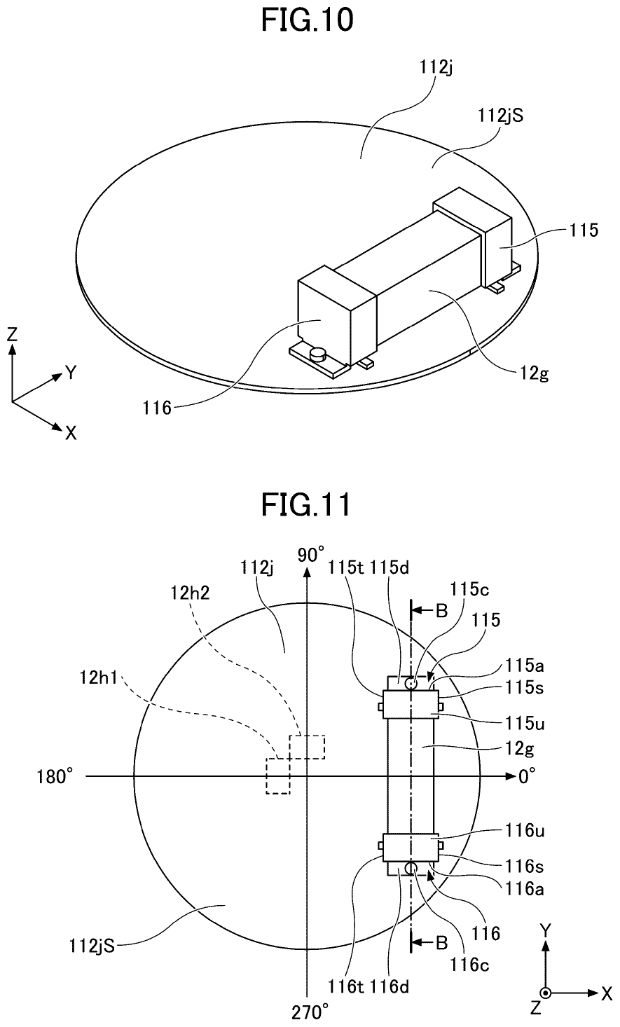

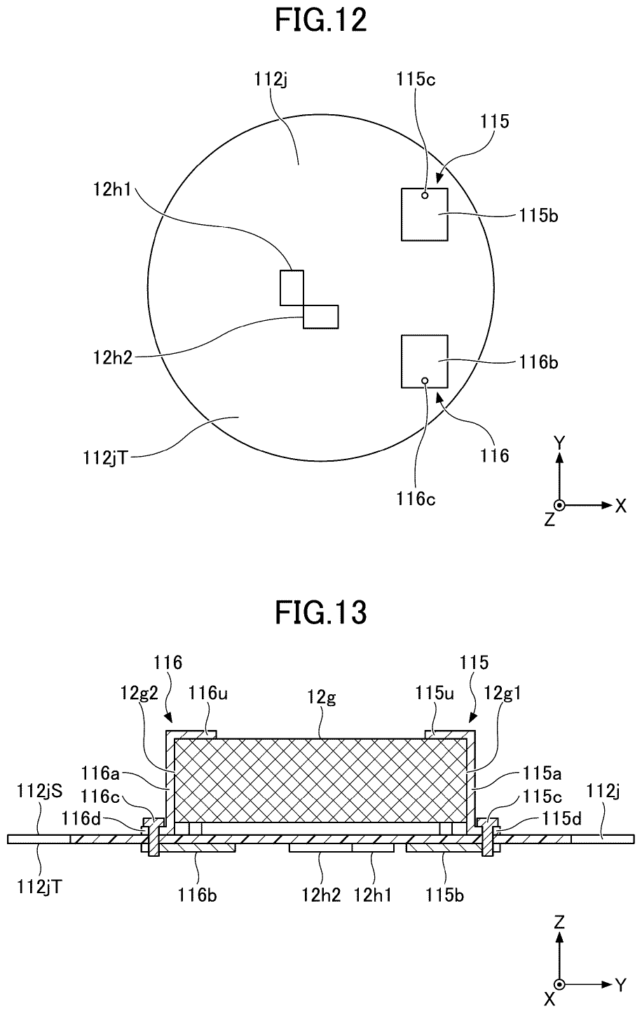

A circuit board provided in the encoder according to the second embodiment will be described as follows. FIG. 10 is a perspective view for describing the configuration of a circuit board 112j as an example of the circuit board in the encoder according to the second embodiment. FIG. 11 is a plan view for describing the configuration of the circuit board 112j as an example of the circuit board in the encoder according to the second embodiment. FIG. 12 is a bottom view for describing the configuration of the circuit board 112j as an example of the circuit board in the encoder according to the second embodiment. FIG. 13 is a cross-sectional view for describing the configuration of the circuit board 112j as an example of the circuit board in the encoder according to the second embodiment. FIG. 13 is a cross-sectional view taken the B-B line in FIG. 11. In FIG. 13, details of an internal structure of the power generation element 12g are omitted.

The circuit board 112j includes a first surface 112jS and a second surface 112jT. The circuit board 112j includes the power generation element 12g on the first surface 112jS. The power generation element 12g is mounted on the first surface 112jS of the circuit board 112j. The second surface 112jT is a surface opposite the first surface 112jS on which the power generation element 12g is mounted. The second surface 112jT is a surface on a magnet side, that is, on a side where the inner magnet 12m1 and the outer magnet 12m2 are situated. The circuit board 112j includes the first magnetic sensor 12h1 and the second magnetic sensor 12h2 on the second surface 112jT.

A first member 115 includes (i) a first vertical plate portion 115a facing the first end portion 12g1 of the power generation element 12g, (ii) an upper plate portion 115u that extends in a negative Y-axis direction from the first vertical plate portion 115a and surrounds a portion of the power generation element 12g, (iii) a side plate portion 115s, and (iv) a side plate portion 115t. The first member 115 also includes a lower plate portion 115d extending in the +Y direction from a −Z side end portion of the first vertical plate portion 115a. In addition, the first member 115 includes a first horizontal plate portion 115b on the second surface 112jT of the circuit board 112j. The first horizontal plate portion 115b extends in the X-axis direction and the Y-axis direction. The first member 115 further includes a first through portion 115c that magnetically connects the lower plate portion 115d to the first horizontal plate portion 115b and that penetrates the circuit board 112j. The first through portion 115c is, for example, a screw having magnetic characteristics.

A second member 116 includes (i) a second vertical plate portion 116a facing the second end portion 12g2 of the power generation element 12g, (ii) an upper plate portion 116u that extends in a positive Y-axis direction from the second vertical plate portion 116a and surrounds a portion of the power generation element 12g, (iii) a side plate portion 116s, and (iv) a side plate portion 116t. The second member 116 also includes a lower plate portion 116d extending in the −Y direction from a −Z side end portion of the second vertical plate portion 116a. In addition, the second member 116 includes a second horizontal plate portion 116b on the second surface 112jT of the circuit board 112j. The second horizontal plate portion 116b extends along the X-axis direction and the Y-axis direction. The second member 116 magnetically connects the lower plate portion 116d to the second horizontal plate portion 116b, and includes a second through portion 116c penetrating the circuit board 112j. The second through portion 116c is, for example, a screw having magnetic characteristics.

In the encoder according to the second embodiment, by further including the first horizontal plate portion 115b and the second horizontal plate portion 116b in the encoder according to the first embodiment, the magnetic field from the outer magnet 12m2 is efficiently transmitted to the power generation element 12g, thereby enabling the power to be generated more efficiently at the power generation element 12g. In addition, in the encoder according to the second embodiment, by providing both the first horizontal plate portion 115b and the second horizontal plate portion 116b on the outer magnet 12m2 side of the circuit board 112j, the magnetic field from the outer magnet 12m2 is more efficiently transmitted to the power generation element 12g, thereby enabling the power to be generated more efficiently at the power generation element 12g.

Further, in the first member 115 and the second member 116, the movement of the power generation element 12g in the Y-axis direction is regulated by the first vertical plate portion 115a and the second vertical plate portion 116a, the movement of the power generation element 12g in the Z-axis direction is regulated by the upper plate portion 115u and the upper plate portion 116u, and the movement of the power generation element 12g in the X-axis direction is regulated by each of the side plate portion 115s, the side plate portion 115t, the side plate portion 116s, and the side plate portion 116t. With this arrangement, each of the first member 115 and the second member 116 has a positioning function of fixing the power generation element 12g to a predetermined position, in addition to having a function of efficiently inducing the magnetic field from the outer magnet 12m2.

Further, the first through portion 115c and the second through portion 116c are implemented by respective screws each of which has magnetic characteristics. In this arrangement, the first member 115 and the second member 116 are fixed to the circuit board 112j by the respective screws, and further, a path along which the magnetic field generated through the outer magnet 12m2 is led from each of the first horizontal plate portion 115b and the second horizontal plate portion 116b to the power generation element 12g can be formed.

In the above example, each of the first horizontal plate portion 115b and the second horizontal plate portion 116b has a rectangular shape when viewed from the bottom. However, the shape of each of the first horizontal plate portion 115b and the second horizontal plate portion 116b is not limited to the above example, and changes to the shape may be made as appropriate.

### Third Embodiment

Hereinafter, the encoder according to a third embodiment will be described. In the encoder according to the third embodiment, the encoder according to the second embodiment further includes a first extension portion in the first horizontal plate portion that extends toward a center position of a given magnetic pole of a given magnet, and includes a second extension portion in the second horizontal plate portion that extends toward a center position of a given magnetic pole of the given magnet.

### Circuit Board

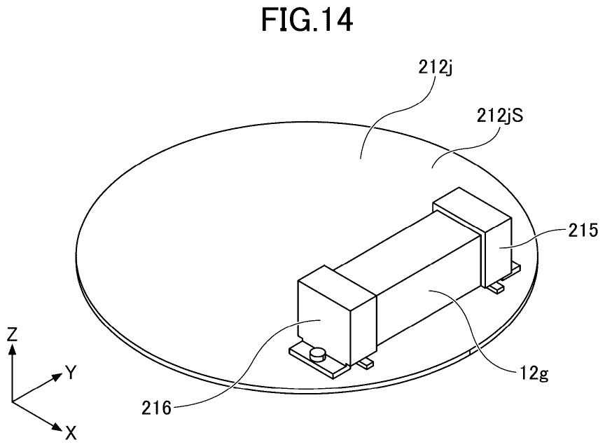

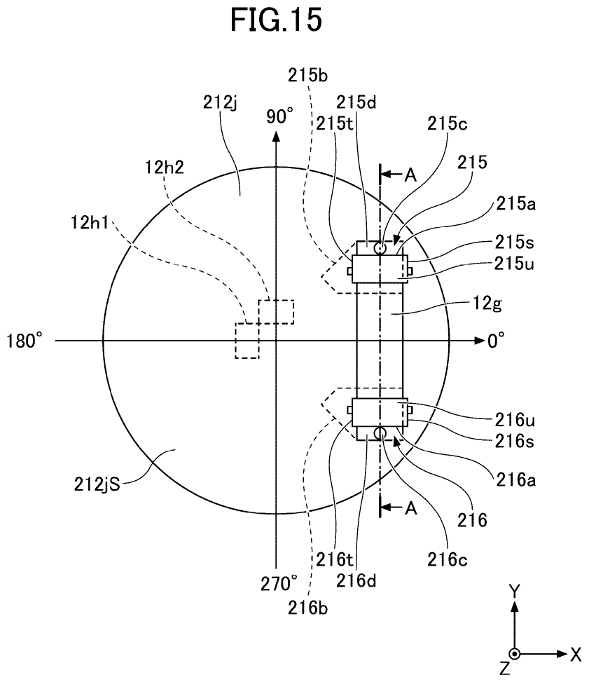

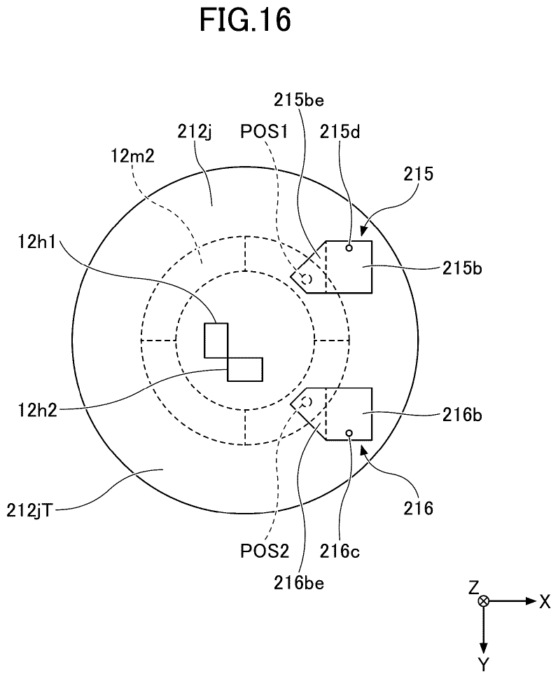

Hereinafter, a circuit board provided in the encoder according to the third embodiment will be described. FIG. 14 is a perspective view for describing the configuration of a circuit board 212j as an example of the circuit board in the encoder according to the third embodiment. FIG. 15 is a plan view for describing the configuration of a circuit board 212j as an example of the circuit board in the encoder according to the third embodiment. FIG. 16 is a bottom view for describing the configuration of the circuit board 212j as an example of the circuit board in the encoder according to the third embodiment. In FIG. 16, a position where the outer magnet 12m2 is situated is indicated by dotted lines. The respective center positions of given magnetic poles in the outer magnet 12m2 are indicated as a position POS1 and a position POS2.

The circuit board 212j includes a first surface 212jS and a second surface 212jT. The circuit board 212j includes the power generation element 12g on the first surface 212jS. The power generation element 12g is mounted on the first surface 212jS of the circuit board 212j. The second surface 212jT is a surface opposite the first surface 212jS on which the power generation element 12g is mounted. The second surface 212jT is on a magnet side, that is, on a side where the inner magnet 12m1 and the outer magnet 12m2 are situated. The circuit board 212j includes a first magnetic sensor 12h1 and a second magnetic sensor 12h2 on the second surface 212jT.

The first member 215 includes (i) a first vertical plate portion 215a facing the first end portion 12g1 of the power generation element 12g, (ii) an upper plate portion 215u that extends in the −Y direction from the first vertical plate portion 215a and surrounds a portion of the power generation element 12g, (iii) a side plate portion 215s, and (iv) a side plate portion 215t. The first member 215 also includes a lower plate portion 215d extending in the +Y direction from a −Z side end portion of the first vertical plate portion 215a. In addition, the first member 215 includes a first horizontal plate portion 215b on the second surface 212jT of the circuit board 212j. The first horizontal plate portion 215b extends in the X-axis direction and the Y-axis direction. The first member 215 magnetically connects the lower plate portion 215d to the first horizontal plate portion 215b, and includes a first through portion 215c penetrating the circuit board 212j. The first through portion 215c is, for example, implemented by a screw having magnetic characteristics.

The first horizontal plate portion 215b includes a first extension portion 215be extending toward the position POS1, which is a center position of a given magnetic pole of the outer magnet 12m2.

The second member 216 includes (i) a second vertical plate portion 216a facing the second end portion 12g2 of the power generation element 12g, (ii) an upper plate portion 216u that extends in the positive Y-axis direction from the second vertical plate portion 216a and surrounds a portion of the power generation element 12g, (iii) a side plate portion 216s, and (iv) a side plate portion 216t. The second member 216 also includes a lower plate portion 216d extending in the −Y direction from the −Z side end portion of the second vertical plate portion 216a. In addition, the second member 216 includes a second horizontal plate portion 216b on the second surface 212jT of the circuit board 212j. The second horizontal plate portion 216b extends in the X-axis direction and the Y-axis direction. The second member 216 magnetically connects the lower plate portion 216d to the second horizontal plate portion 216b, and includes a second through portion 216c penetrating the circuit board 212j. The second through portion 216c is, for example, implemented by a screw having magnetic characteristics.

The second horizontal plate portion 216b includes a second extension portion 216be extending toward the position POS2, which is a center position of a given magnetic pole of the outer magnet 12m2.

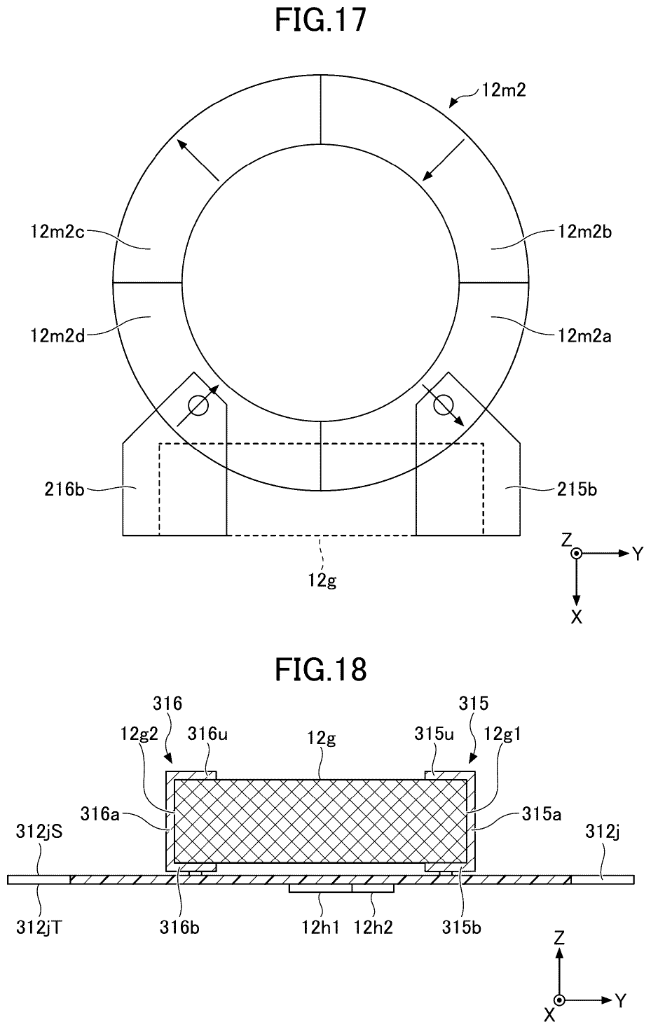

A positional relationship between the first horizontal plate portion 215b of the first member 215, the second horizontal plate portion 216b of the second member 216, and the outer magnet 12m2 will be described as follows. FIG. 17 is a diagram for describing the positional relationship between the magnet and the horizontal plate portions in the encoder according to the third embodiment.

As shown in FIG. 17, the power generation element 12g is provided at a position displaced radially outward from the outer magnet 12m2 in plan view. When the power generation element 12g is disposed outside the magnets 12m2a to 12m2d, generated power increases more than when the power generation element 12g is disposed at a position facing each of the magnets 12m2a to 12m2d. The encoder 12 is provided such that each of the first horizontal plate portion 215b and the second horizontal plate portion 216b extends in lateral directions (X-axis direction and Y-axis direction) toward the center position of a given magnetic pole of the outer magnet 12m2 as shown by a circle in FIG. 17. By extending each of the first horizontal plate portion 215b and the second horizontal plate portion 216b toward the center position of the given magnetic pole of the outer magnet 12m2, the magnetic field applied between the first end portion 12g1 and the second end portion 12g2 of the power generation element 12g can be increased. By increasing the magnetic field applied between the first end portion 12g1 and the second end portion 12g2 of the power generation element 12g, efficiency in generating the power at the power generation element 12g can be increased.

In the encoder according to the third embodiment, by further including the horizontal plate portions having respective extension portions in the encoder according to the second embodiment, the magnetic field generated from the outer magnet 12m2 is led to the power generation element 12g through the first member 215 and the second member 216. In the encoder according to the third embodiment, the magnetic field generated from the outer magnet 12m2 is led to the power generation element 12g through the first member 215 and the second member 216, and thus power can be efficiently generated at the power generation element 12g.

### Fourth Embodiment

Hereinafter, the encoder according to a fourth embodiment will be described. In the encoder according to the fourth embodiment, the first member in the encoder according to the first embodiment further includes a first horizontal plate portion extending in the first direction and the second direction, and the second member in the encoder according to the first embodiment further includes a second horizontal plate portion extending in the first direction and the second direction. The encoder according to the fourth embodiment further includes a substrate on which the power generation element is mounted. In the encoder according to the fourth embodiment, the first member includes a first horizontal plate portion provided between the substrate and the power generation element, and the second member includes a second horizontal plate portion provided between the substrate and the power generation element.

### Circuit Board

The circuit board in the encoder according to the fourth embodiment will be described as follows. FIG. 18 is a cross-sectional view for describing the configuration of a circuit board 312j in the encoder according to the fourth embodiment.

The circuit board 312j includes a first surface 312jS and a second surface 312jT. The circuit board 312j includes the power generation element 12g on the first surface 312jS. The power generation element 12g is mounted on the first surface 312jS of the circuit board 312j. The second surface 312jT is a surface opposite the first surface 312jS on which the power generation element 12g is mounted. The second surface 312jT is a surface on a magnet side, that is, on a side where the inner magnet 12m1 and the outer magnet 12m2 are situated. The circuit board 312j includes the first magnetic sensor 12h1 and the second magnetic sensor 12h2 on the second surface 312jT.

The encoder according to the fourth embodiment includes a first member 315 on the +Y side of the power generation element 12g, and includes a second member 316 on the −Y side of the power generation element 12g. Each of the first member 315 and the second member 316 is made of a magnetic material.

The first member 315 includes (i) a first vertical plate portion 315a facing the first end portion 12g1 of the power generation element 12g, (ii) an upper plate portion 315u extending in the negative Y-axis direction from the first vertical plate portion 315a and surrounding a portion of the power generation element 12g, and (iii) side plate portions (not shown). The first member 315 also includes a first horizontal plate portion 315b extending in the −Y direction from a −Z side end portion of the first vertical plate portion 315a.

The second member 316 includes (i) a second vertical plate portion 316a facing the first end portion 12g1 of the power generation element 12g, (ii) an upper plate portion 316u that extends in the positive Y-axis direction from the second vertical plate portion 316a and surrounds a portion of the power generation element 12g, and (iii) side plate portions (not shown). The second member 316 also includes a second horizontal plate portion 316b extending in the +Y direction from a −Z side end portion of the second vertical plate portion 316a.

In the encoder 12 according to the fourth embodiment, by including the first horizontal plate portion 315b and the second horizontal plate portion 316b on an outer magnet 12m2-side of the power generation element 12g in the encoder according to the first embodiment, the magnetic field generated from the outer magnet 12m2 can be led to the power generation element 12g. Since the magnetic field from the outer magnet 12m2 is led to the power generation element 12g through the first member 315 and the second member 316, the power generation element 12g can efficiently generate the power.

The first horizontal plate portion 315b and the second horizontal plate portion 316b may include respective extension portions each of which extends toward the center position of a given magnetic pole, as described in the first horizontal plate portion and the second horizontal plate portion in the encoder according to the third embodiment.

### Modifications

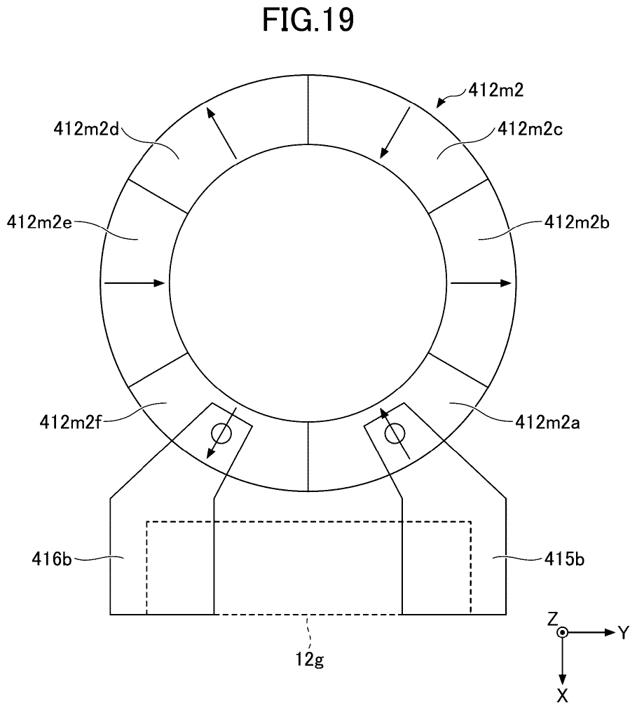

Hereinafter, an example in which the number of poles of the outer magnet is changed will be described. FIG. 19 is a diagram for describing an example in which the number of poles of the outer magnet is changed in the encoder according to a modified embodiment.

An outer magnet 412m2 is a magnet having six poles. The outer magnet 412m2 includes a magnet 412m2a, a magnet 412m2b, a magnet 412m2c, a magnet 412m2d, a magnet 412m2e, and a magnet 412m2f. Each of magnets 412m2a, 412m2c, and 412m2e has a magnetic field that is directed inward. Each of magnets 412m2b, 412m2d, and 412m2f has a magnetic field that is directed outward.

Each of a first horizontal plate portion 415b and a second horizontal plate portion 416b are provided so as to extend to a center position of a given magnetic pole. In this arrangement, the magnetic field from the outer magnet 412m2 is efficiently led to the power generation element 12g.

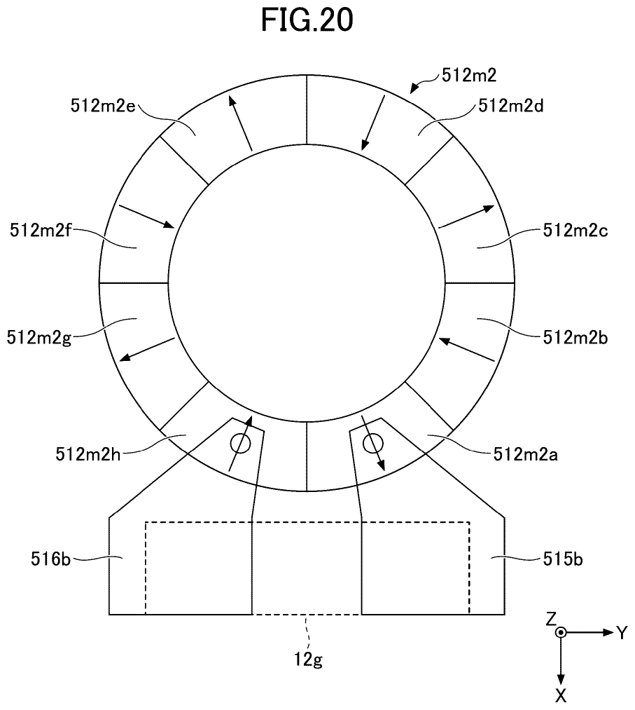

Hereinafter, an example of the outer magnet having eight poles will be described. FIG. 20 is a diagram for describing the encoder according to a modified embodiment in which the number of poles of the outer magnet is changed.

An outer magnet 512m2 is a magnet having eight poles. An outer magnet 512m2 includes a magnet 512m2a, a magnet 512m2b, a magnet 512m2c, a magnet 512m2d, a magnet 512m2e, a magnet 512m2f, a magnet 512m2g, and a magnet 512m2h. Each of magnets 512m2a, 512m2c, 512m2e, and 512m2g has a magnetic field that is directed outward. Each of magnets 512m2b, 512m2d, 512m2f, and 512m2h has a magnetic field that is directed inward.

Each of a first horizontal plate portion 515b and a second horizontal plate portion 516b is provided so as to extend to a center position of a given magnetic pole. In this arrangement, the magnetic field from the outer magnet 512m2 can be efficiently led to the power generation element 12g.

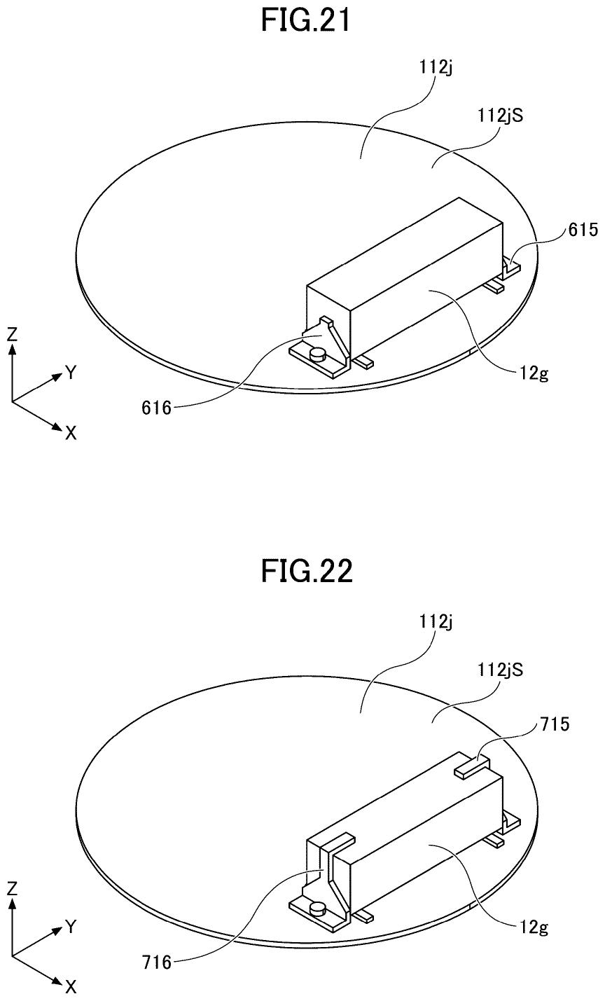

Hereinafter, a modified shape of the vertical plate portion of each of the first member and the second member will be described. The power generation element 12g has a Wiegand wire along a centerline in the X-axis direction and the Z-axis direction. In this case, it is desirable to concentrate the magnetic flux at a middle portion of each side surface of the power generation element 12g. In order to concentrate the magnetic flux at the middle portion of each side surface of the power generation element 12g, it is desirable to decrease the width of a vertical plate portion at the middle portion (X-axis direction and Z-axis direction) of each side surface of the power generation element 12g. FIGS. 21 to 23 are diagrams for describing an example in which the width of the vertical plate portion is decreased at the middle portion of the power generation element 12g in the encoder according to the present embodiment.

FIGS. 21 to 23 are diagrams for describing the encoder according to a modified embodiment. FIGS. 21 to 23 are diagrams showing a modified shape of the vertical plate portion of each of the first member and the second member.

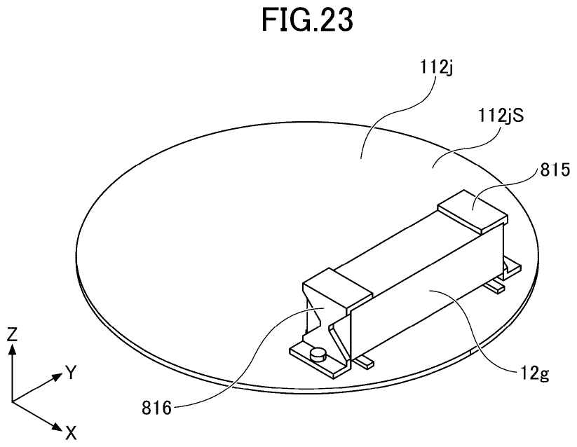

In an example in FIG. 21, each of a first member 615 and a second member 616 includes a vertical plate portion whose width in the X-axis direction decreases toward a center position in a positive Z-axis direction. In an example in FIG. 22, each of a first member 715 and a second member 716 includes a vertical plate portion including (i) a portion whose width in the X-axis direction decreases toward a center position in the positive Z-axis direction, and (ii) a portion that extends in the positive Z-axis direction from the center position and that has the same width as the portion whose width in the X-axis direction decreases toward the center position described in (i). Also, each of a first member 715 and a second member 716 includes an upper plate portion having the same width in the X-axis direction and extending in the Y-axis direction. In an example of FIG. 23, each member of a first member 815 and a second member 816 includes a vertical plate portion including (i) a portion whose width in the X-axis direction decreases toward a center position in the positive Z-axis direction, and (ii) a portion whose width in the X-axis direction increases in the positive Z-axis direction from the center position. Also, each of the first member 815 and the second member 816 includes an upper plate portion having the same width in the X-axis direction and extending in the Y-axis direction.

As shown in FIG. 21 to FIG. 23, by decreasing the width of a middle portion of each vertical plate portion, the magnetic field can be concentrated at each end portion of the Wiegand wire to further improve efficiency in generating the power.

Although in the above example, the Wiegand wire is provided along the centerline of the power generation element 12g in the X-axis direction and the Z-axis direction, a location where the width of each vertical plate portion is decreased may be appropriately changed depending on the location of the Wiegand wire.

The embodiments disclosed herein are presented by way of example in all respects, and these embodiments are not limiting. The above embodiments may be omitted, replaced, or changed in various forms without departing from the scope and gist of the present disclosure.

In an encoder in the present disclosure, power can be efficiently generated at a power generation element.

What is claimed is:

1. An encoder comprising:
a power generation element including a first end portion and a second end portion spaced apart from the first end portion in a first direction, the power generation element being configured to generate power upon occurrence of a condition in which a magnetic field generated by one or more magnets fixed to a rotary shaft varies between the first end portion and the second end portion;
a first member including a first vertical plate portion that is provided facing the first end portion and extends in a second direction intersecting the first direction, the first member being formed of a magnetic material; and
a second member spaced apart from the first member, and including a second vertical plate portion that is provided facing the second end portion and extends in the second direction, and the second member being formed of the magnetic material.

2. The encoder as claimed in claim 1,
wherein the first member includes a first horizontal plate portion extending in the first direction, and
wherein the second member includes a second horizontal plate portion extending in the first direction.

3. The encoder as claimed in claim 2,
wherein the first horizontal plate portion includes a first extension portion extending toward a center position of a first magnetic pole of a given magnet among the one or more magnets, and
wherein the second horizontal plate portion includes a second extension extending toward a center position of a second magnetic pole of the given magnet.

4. The encoder as claimed in claim 2, further comprising:
a substrate having (i) a first surface on which the power generation element is mounted, and (ii) a second surface opposite the first surface, and on which the one or more magnets are situated,
wherein the first member includes a first horizontal plate portion provided on the second surface, and
wherein the second member includes a second horizontal plate portion provided on the second surface.

5. The encoder as claimed in claim 4,
wherein the first member includes a first through portion passing through the substrate, and
wherein the second member includes a second through portion passing through the substrate,

6. The encoder as claimed in claim 5, wherein each of the first through portion and the second through portion includes a screw having a magnetic characteristic.

7. The encoder as claimed in claim 2, further comprising:
a substrate on which the power generation element is provided,
wherein the first horizontal plate portion of the first member is provided between the substrate and the power generation element, and
wherein the second horizontal plate portion of the second member is provided between the substrate and the power generation element.

8. The encoder as claimed in claim 1,
wherein in the second direction, a portion of each of the first vertical plate portion and the second vertical plate portion is narrower than a portion of the power generation element, or
wherein in a third direction intersecting the first direction and the second direction, a portion each of the first vertical plate portion and the second vertical plate portion is narrower than a portion of the power generation element.
